(19) United States
(12) Patent Application Publication
(10) Pub. No.: US 2007/0257357 A1
(43) Pub. Date: Nov. 8, 2007

(54) Forcing gas trapped between two components into cavities

(76) Inventors: Alok Sharan, Corvallis, OR (US); Jeffrey R. Pollard, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/479,915

(22) Filed: Jun. 30, 2006

Related U.S. Application Data
(63) Continuation-in-part of application No. 11/416,709, filed on May 3, 2006.

(51) Int. Cl. H01L 23/12; H01L 21/00

(52) U.S. Cl. 257/704; 438/50

(57) ABSTRACT

An apparatus includes a first component and a second component. The apparatus includes one or more cavities within one or more of the first and the second components. The apparatus includes one or more channels within one or more of the first and the second components. The channels are fluidically interconnectable with the cavities. Upon pressing the first component against the second component to bond the first component to the second component, gas trapped between the first and the second components is forced into the cavities via the channels.

### RELATED APPLICATIONS

The present patent application is a continuation-in-part of the pending patent application entitled “Packaged MEMS Device Assembly,” filed on May 3, 2006, and assigned Ser. No. 11/416,709 [attorney docket no. 200504328-1].

### BACKGROUND

In semiconductor processing, it is common to have to bond two surfaces together, such as two semiconductor wafer surfaces. During the bonding process, the two surfaces are pressed against one another. As a result, air, or other gas, can become trapped between the two surfaces. This trapped gas can cause defects, such as Newton rings, within the electronic devices that are formed from the semiconductor wafers, which can reduce device yield and thus increase manufacturing cost.

### BRIEF DESCRIPTION OF THE DRAWINGS

FIGS. 1A, 1B, and 1C are diagrams depicting two components to be pressed against one another for bonding, according to different embodiments of the invention.

FIGS. 2A and 2B are diagrams showing how channels and a cavity of two components remove trapped gas between the two components during bonding, via the gas being forced into the cavity through the channels, according to an embodiment of the invention.

FIG. 3 is a flowchart of a method, according to an embodiment of the invention.

### DETAILED DESCRIPTION OF THE DRAWINGS

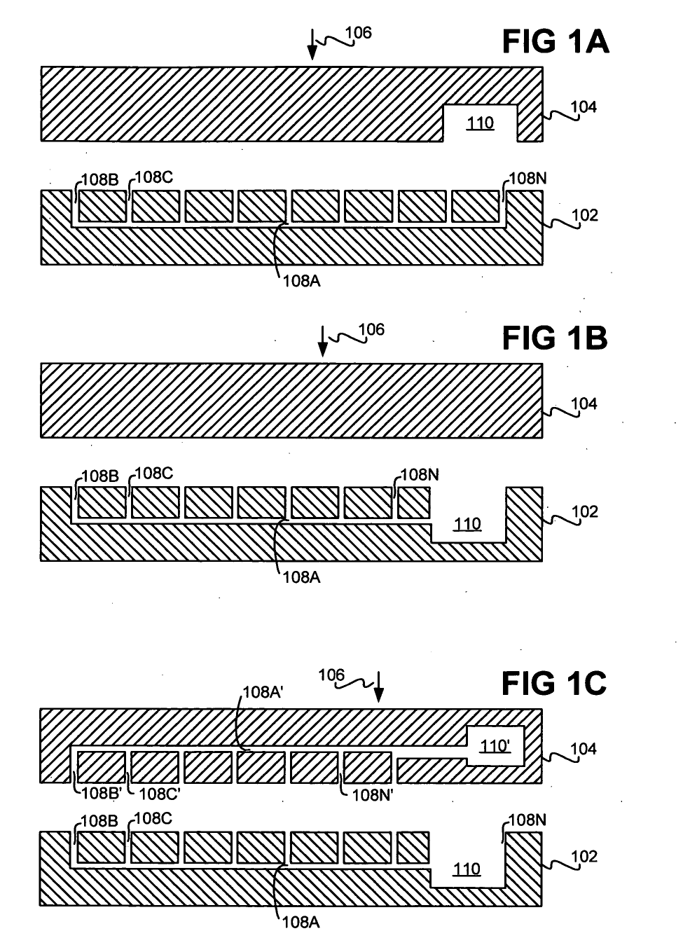

FIGS. 1A, 1B, and 1C show two components 102 and 104 to be pressed against one another to bond the components 102 and 104 together, according to different embodiments of the invention. Both of the components 102 and 104 may be semiconductor wafers, or another type of component. For instance, the components 102 and 104 together may implement a number of micro-electromechanical systems (MEMS) devices over their dies. The substrates of the components 102 and 104 may be silicon, glass, plastic, or another type of material.

In FIG. 1A, the component 102 includes a number of channels 108A, 108B, 108C, . . . , 108N, collectively referred to as the channels 108, whereas the component 104 includes a cavity 110. Upon pressing the component 102 against the component 104, any air or other gas trapped between the components 102 and 104 is forced into the cavity 110 via the channels 108. The channels 108 are said to be fluidically interconnected with the cavity 110 upon pressing the components 102 and 104 together. While just one cavity 110 is depicted in FIG. 1A, there may be more than one such cavity.

In FIG. 1B, the component 102 includes the channels 108 and the cavity 110. Therefore, the embodiment of FIG. 1B differs from that of FIG. 1A in that the latter embodiment has the channels 108 in one component and the cavity 110 in another component 110. By comparison, in the embodiment of FIG. 1B, one component includes both the channels 108 and the cavity 110. While just one cavity 110 is depicted in FIG. 1B, there may be more than one such cavity. Upon pressing the components 102 and 104 together in FIG. 1B, as indicated by the arrow 106, any air or other gas trapped between the components 102 and 104 is again forced in the cavity 110 via the channels 108.

In FIG. 1C, the component 102 includes the channels 108 and the cavity 110, whereas the component 104 includes channels 108A′, 108B′, 108C′, . . . , 108N′, collectively referred to as the channels 108′, and a cavity 110′. Upon pressing the component 102 against the component 104, as indicated by the arrow 106, any air or other gas trapped between the components 102 and 104 is forced in the cavities 110 and 110′ via the channels 108 and 108′. The channels 108 are fluidically interconnected with the cavity 110, and also may be fluidically interconnected with the cavity 110′ via the channels 108′. Likewise, the channels 108′ are fluidically interconnected with the cavity 110′, and also may be fluidically interconnected with the cavity 110 via the channels 108.

The cavity 110 of FIGS. 1A, 1B, and 1C is directly exposed at the exterior surface of the component of which it is a part. By comparison, the cavity 110′ of FIG. 1C is exposed at the exterior surface of the component 104 just via the channels 108′, and is not directly exposed at the exterior surface of the component 104. There may be more than one of the cavity 110 and/or the cavity 110′ in the embodiment of FIG. 1C, in the component 102 and/or the component 104. The embodiment of FIG. 1C also differs from that of FIG. 1B and that of FIG. 1A insofar as each of the components 102 and 104 includes channels, whereas in the embodiments of FIGS. 1A and 1B, just one of the components 102 and 104 includes the channels 108.

In general, then, there are one or more cavities within one or more of the components 102 and 104, and there are one or more channels within one or more of the components 102 and 104. The channels are fluidically interconnectable with the cavities. Upon pressing the component 102 against the component 104 to bond the components 102 and 104 together, air or other gas trapped between the components 102 and 104 is forced into the cavities via the channels, and thus is removed from being trapped between the components 102 and 104.

The embodiments depicted in FIGS. 1A, 1B, and 1C are thus examples of how such channels and cavity or cavities may be configured in relation to the components 102 and 104, and do not represent all embodiments of the invention and do not otherwise limit the invention. Where the components 102 and 104 are semiconductor or other types of wafers defining a number of dies corresponding to individual electronic devices, the channels may be formed between the dies. Alternatively, the channels may be formed within the dies themselves, in such a way so as not to disturb the electronics and other functional parts of the dies.

It is noted that the terminology “channel” as used herein is intended in a general and all-encompassing sense, and is that which is fluidically connected to the one or more cavities. As such, the terminology “channel” encompasses pipes, circuitous pathways, meshes, and other types of channels. The terminology “channel” does not imply, for instance, a straight-line pathway, such that the channel may be curved, and so on.

Furthermore, it is noted that while some specific items have been referred to as channels, and other specific items have been referred to as cavities, in one embodiment, a channel may be a cavity, and vice-versa. For instance, a relatively voluminous channel may serve as a cavity as well. As another example, a cavity that is fluidically connected to another channel may serve as a channel as well. Thus, the terminology “channel” is also intended herein to encompass a channel having cavity functionality, to store trapped gas, and the terminology “cavity” is also intended herein to encompass a cavity having channel functionality, to fluidically connect to a cavity.

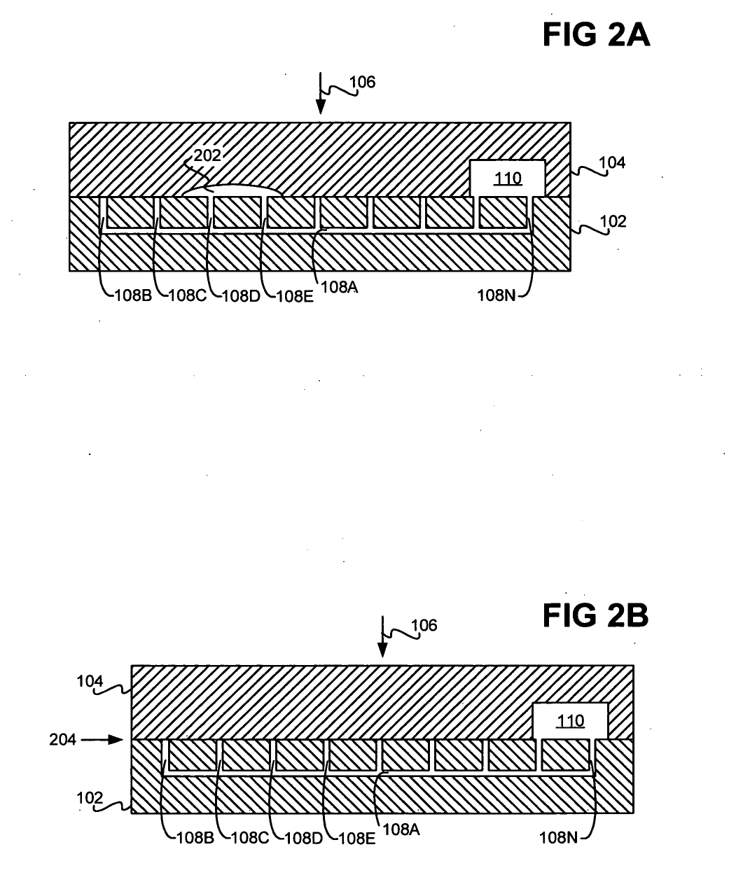

FIGS. 2A and 2B show how trapped gas between the components 102 and 104 is forced into the cavity 110 via the channels 108, according to an embodiment of the invention. The components 102 and 104 depicted in FIGS. 2A and 2B are particularly those of FIG. 1A. However, the utilization of the embodiment of FIG. 1A in FIGS. 2A and 2B is just for arbitrary descriptive certainty, and other embodiments may also be utilized in relation to FIGS. 2A and 2B. As before, the components 102 and 104 include the cavity 110 and the channels 108, the latter particularly further including the channels 108D and 108E identified in FIGS. 2A and 2B.

In FIG. 2A, the component 104 is being pressed against the component 102, as indicated by the arrow 106. Pressing the components 102 and 104 together in this way has resulted in a pocket 202 of air, or another gas, forming between the components 102 and 104. The pocket 202 trapped between the components 102 and 104 has indeed slightly deformed the component 104. Any electronic or other devices being formed on the components 102 and 104 at the location of the pocket 202 may be defective.

For example, the pocket 202 may result in a Newton ring forming, where the devices implemented by the components 102 and 104 are optical-related devices. A Newton ring is an interference pattern caused by the reflection of light between two surfaces, a spherical surface and an adjacent flat surface. It appears as a series of concentric, alternating light and dark rings centered at the point of contact between the two surfaces. The light rings are caused by constructive interference between the incident and reflected light rays, while the dark rings are caused by destructive interference.

In FIG. 2B, however, the pocket 202 has dissipated, such that the component 104 is no longer slightly deformed. The air or other gas trapped within the pocket 202 of FIG. 2A has been forced, via the pressure applied to the component 104 to press the component 104 against the component 102 as indicated by the arrow 106, into the cavity 110 through the channels 108. As such, the component 104 is no longer slightly deformed since the pocket 202 of FIG. 2A is not present in FIG. 2B.

In particular, the air or other gas trapped within the pocket 202 of FIG. 2A is forced into the cavity 110 via the channels 108A, 108D, and 108E. That is, the air or other gas trapped within the pocket 202 of FIG. 2A is forced into the channels 108D and 108D into the channel 108A, from the channel 108A into the cavity 110. In this way, pockets of gas or air, such as the pocket 202 of FIG. 2A are eliminated during bonding of two components 102 and 104, preventing defects caused by such pockets, such as Newton rings.

It is noted that the components 102 and 104 define a bonding interface 204 at the surfaces where the components 102 and 104 contact one another. The components 102 and 104 may be bonded in any of a number of different ways. For instance, the bonding may be plasma enhanced or plasma activated, such that one or both of the surfaces of the components 102 and 104 are plasma treated prior to pressing the components 102 and 104 together. The bonding may further or alternatively include anodic bonding, adhesive bonding, and/or another type of bonding.

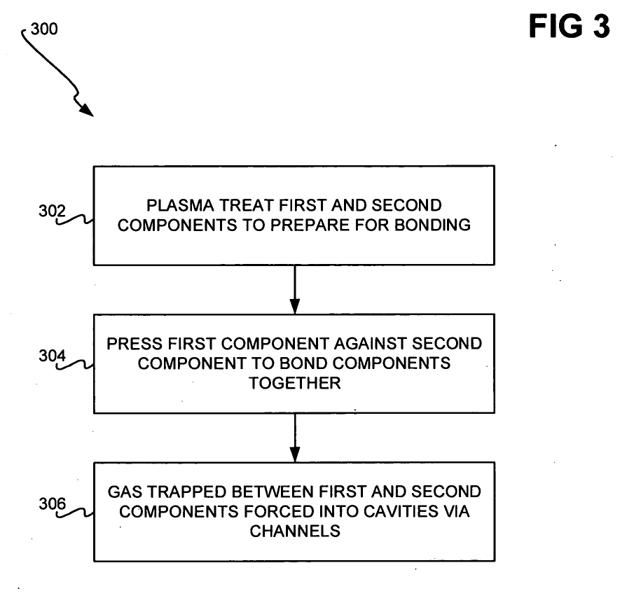

FIG. 3 shows a method 300, according to an embodiment of the invention. In one embodiment, where the components 102 and 104 are to be plasma-enhanced or plasma-activated bonded together, either or both of both the components 102 and 104 are initially plasma treated (302). Where a different type of bonding is to occur between the two components 102 and 104, part 302 of the method 300 is not performed.

The component 104 is then pressed against the component 102 to bond the components 102 and 104 together (304). The terminology of pressing the first component against the second component is intended to be inclusive of the second component being pressed against the first component and the two components being pressed together. That is, ultimately in effect, the first component is indeed pressed or forced against the second component.

Any air or other gas that is trapped between the components 102 and 104 is forced into one or more cavities via channels (306). Representative performance of part 306 has been illustratively depicted and described in relation to FIGS. 2A and 2B. More than one pocket 202 may be initially formed, but all such pockets are ultimately dissipated by the air or other gas of such pockets being forced into the one or more cavities through the channels. Such air or other gas being forced into the cavities via the channels results from pressing the component 104 against the component 102.

We claim:

1. An apparatus comprising:
a first component;
a second component;
one or more cavities within one or more of the first and the second components; and,
one or more channels within one or more of the first and the second components and fluidically interconnectable with the cavities such that upon pressing the first component against the second component to bond the first component to the second component, gas trapped between the first and the second components is forced into the cavities via the channels.

2. The apparatus of claim 1, wherein the first component is a first wafer and the second component is a second wafer, the first and the second wafers together implementing a plurality of micro-electromechanical systems (MEMS) devices.

3. The apparatus of claim 1, wherein the cavities are located within one of the first and the second components.

4. The apparatus of claim 3, wherein the channels are located within the one of the first and the second components.

5. The apparatus of claim 3, wherein the channels are located within another of the first and the second components.

6. The apparatus of claim 1, wherein the cavities are located within both of the first and the second components.

7. The apparatus of claim 1, wherein the channels are located within one of the first and the second components.

8. The apparatus of claim 1, wherein the channels are located within both of the first and the second components.

9. The apparatus of claim 1, wherein at least one of the cavities are each directly exposed at an exterior surface of the one or more of the first and the second components prior to pressing of the first component against the second component.

10. The apparatus of claim 1, wherein at least one of the cavities are each exposed at an exterior surface of the one or more of the first and the second components via at least one of the channels prior to pressing of the first component against the second component.

11. The apparatus of claim 1, further comprising a bonding interface between the first component and the second component and resulting from plasma treatment of the first and the second components prior to pressing the first component against the second component.

12. An apparatus comprising:
a first component;
a second component; and,
means for removing gas trapped between the first and the second components upon the first component being pressed against the second component to bond the first component to the second component.

13. The apparatus of claim 12, wherein the first component is a first wafer and the second component is a second wafer, the first and the second wafers together implementing a plurality of micro-electromechanical systems (MEMS) devices.

14. The apparatus of claim 12, wherein the means comprises:
one or more cavities within one or more of the first and the second components; and,
one or more channels within one or more of the first and the second components and fluidically interconnectable with the cavities such that the gas trapped between the first and the second components is forced into the cavities via the channels.

15. The apparatus of claim 14, wherein the cavities are located within one of the first and the second components.

16. The apparatus of claim 15, wherein the channels are located within the one of the first and the second components.

17. The apparatus of claim 12, further comprising a bonding interface between the first component and the second component and resulting from plasma treatment of the first and the second components prior to pressing the first component against the second component.

18. A method comprising:
pressing a first component against a second component, the first and the second components having one or more cavities and one or more channels fluidically interconnectable with the cavities; and,
forcing gas trapped between the first and the second components into the cavities via the channels, resulting from pressing the first component against the second component.

19. The method of claim 18, further comprising initially plasma treating one or more of the first and the second components such that the first and the second components are plasma-enhanced bonded together upon pressing the first component against the second component.

20. The method of claim 18, wherein the first component is a first wafer and the second component is a second wafer, the first and the second wafers together implementing a plurality of micro-electromechanical systems (MEMS) devices.
